(19) United States
(12) Patent Application Publication
(10) Pub. No.: US 2026/0157076 A1
(43) Pub. Date: Jun. 4, 2026

(54) Electroluminescent Display Device

(71) Applicant: LG Display Co., Ltd., Seoul (KR)

(72) Inventor: YunHee Choi, Paju-si (KR)

(21) Appl. No.: 19/335,403

(22) Filed: Sep. 22, 2025

(30) Foreign Application Priority Data
Dec. 4, 2024 (KR) 10-2024-0179012

(51) Int. Cl. H10K 59/00; H10K 59/35

(52) U.S. Cl. CPC H10K 59/771; H10K 59/353

(57) ABSTRACT

An electroluminescent display device is provided, a substrate including a first sub-pixel, a second sub-pixel, and a third sub-pixel, a first electrode in each of the first to third sub-pixels on the substrate, a light emitting unit on the first electrode, and a second electrode on the light emitting unit, wherein the light emitting unit includes a first stack including a first light emitting layer, a second stack including a second light emitting layer, and a charge generation layer disposed between the first stack and the second stack, wherein the charge generation layer includes a first charge generation layer disposed in the first sub-pixel and a second charge generation layer disposed in the second sub-pixel and the third sub-pixel, and wherein the second charge generation layer does not overlap with the first sub-pixel and is continuous across the second sub-pixel and the third sub-pixel.

### CROSS-REFERENCE TO RELATED APPLICATIONS

This application claims priority under 35 U.S.C. § 119(a) to the Republic of Korea Patent Application No. 10-2024-0179012, filed on Dec. 4, 2024, the entire contents of which are hereby expressly incorporated by reference into the present application.

### TECHNICAL FIELD

The present disclosure relates to an electroluminescent display device.

### BACKGROUND

The electroluminescent display device includes a first electrode, a second electrode, and a light emitting layer disposed between the first electrode and the second electrode, and displays an image by emitting the light emitting layer by an electric field between the first electrode and the second electrode.

The electroluminescent display device may include a plurality of stacks disposed above and below a charge generation layer. In this case, a leakage current may occur between adjacent sub-pixels through the charge generation layer, so a method of disconnecting the charge generation layer between adjacent sub-pixels has been devised.

However, in this case, there is a problem in that the leakage current occurs in a vertical direction due to a difference in an amount of remaining charge between a stack disposed below the charge generation layer and a stack disposed above the charge generation layers, resulting in a screen defect such as flash.

### SUMMARY

The present disclosure has been made in view of the above problems and it is an aspect of the present disclosure to provide an electroluminescent display device that can eliminate screen defects such as flash by preventing leakage current in a vertical direction by increasing a potential of a charge generation layer by lowering a horizontal resistance between sub-pixels.

In accordance with an aspect of the present disclosure, the above and other technical effects can be accomplished by the provision of an electroluminescent display device comprising a substrate including a first sub-pixel, a second sub-pixel, and a third sub-pixel, a first electrode in each of the first to third sub-pixels on the substrate, a light emitting unit on the first electrode, and a second electrode on the light emitting unit, wherein the light emitting unit includes a first stack including a first light emitting layer, a second stack including a second light emitting layer, and a charge generation layer disposed between the first stack and the second stack, wherein the charge generation layer includes a first charge generation layer disposed in the first sub-pixel and a second charge generation layer disposed in the second sub-pixel and the third sub-pixel, and wherein the second charge generation layer does not overlap with the first sub-pixel and is continuous across the second sub-pixel and the third sub-pixel.

In addition, in accordance with an aspect of the present disclosure, the above and other technical effects can be accomplished by the provision of an electroluminescent display device comprising a plurality of pixels including a first sub-pixel, a second sub-pixel, and a third sub-pixel, and arranged in a first directions and a second direction, and a light emitting unit disposed in the plurality of pixels and including a charge generation layer, wherein the charge generation layer includes a first charge generation layer disposed in the first sub-pixel and a second charge generation layer that does not overlap with the first sub-pixel and is continuous across the second sub-pixel and the third sub-pixel, and wherein the second charge generation layer is continuous across two or more pixels arranged in the first direction.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a schematic cross-sectional view of an electroluminescent display device according to an embodiment of the present disclosure.

FIG. 2 is a schematic cross-sectional view of a light emitting unit according to an embodiment of the present disclosure.

FIG. 3 is a schematic cross-sectional view of a light emitting unit according to another embodiment of the present disclosure.

FIG. 4 is a schematic plan view of an electroluminescent display device according to an embodiment of the present disclosure.

FIG. 5 is a schematic plan view of an electroluminescent display device according to an embodiment of the present disclosure.

FIG. 6 is a schematic plan view of an electroluminescent display device according to an embodiment of the present disclosure.

FIG. 7 is a schematic plan view of an electroluminescent display device according to an embodiment of the present disclosure.

FIG. 8 is a schematic plan view of an electroluminescent display device according to an embodiment of the present disclosure.

FIG. 9 is a schematic cross-sectional view of a light emitting unit according to another embodiment of the present disclosure.

FIG. 10 is a schematic cross-sectional view of a light emitting unit according to another embodiment of the present disclosure.

FIG. 11 is a schematic cross-sectional view of a light emitting unit according to another embodiment of the present disclosure.

FIG. 12 is a schematic plan view of an electroluminescent display device according to an embodiment of the present disclosure.

FIG. 13 is a schematic plan view of an electroluminescent display device according to an embodiment of the present disclosure.

FIG. 14 is a schematic plan view of an electroluminescent display device according to an embodiment of the present disclosure.

FIG. 15 is a schematic plan view of an electroluminescent display device according to an embodiment of the present disclosure.

FIG. 16 is a schematic plan view of an electroluminescent display device according to an embodiment of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art. Further, the scope of the present disclosure is only defined by of the accompanying claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’, and ‘include’ described in the present disclosure are used, another portion may be added unless ‘only˜’ is used. The terms of a singular form may include plural forms unless referred to the contrary.

In interpreting the components, it is interpreted as including an error range even if there is no separate explicit description of an error range.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper”, and the like, may be used herein to describe a relationship between elements as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)”, etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” or “attached” to another component, that component may be connected, coupled, or attached directly to that other component, but it should be understood that other components may be interposed between each component that may be connected, coupled, or attached indirectly, without any specific description.

It should be understood that, if a component or layer is stated to be “in contact” or “overlapping” with another component or layer, the component or layer may be in direct contact or overlapping with another component or layer, but other components may be interposed between the components that may be indirectly in contact or overlapping without explicit description.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first element, a second element, or a third element” compasses the combination of all three listed elements, combinations of any two of the three elements, as well as each individual element, the first element, the second element, or the third element.

“First direction”, “second direction”, “third direction”, “X-axis direction”, “Y-axis direction”, and “Z-axis direction” should not be interpreted only as a geometric relationship perpendicular to each other, but may mean that the configuration of the present disclosure has a wider direction within a range in which the configuration of the present disclosure may functionally act.

Features of each of the various examples of the present disclosure may be partially or entirely coupled or combined with each other, technically various interworking and driving are possible, and each of the examples may be independently implemented with respect to each other or may be implemented together in a related relationship.

Hereinafter, one embodiment of the present disclosure will be described in detail with reference to the accompanying drawings.

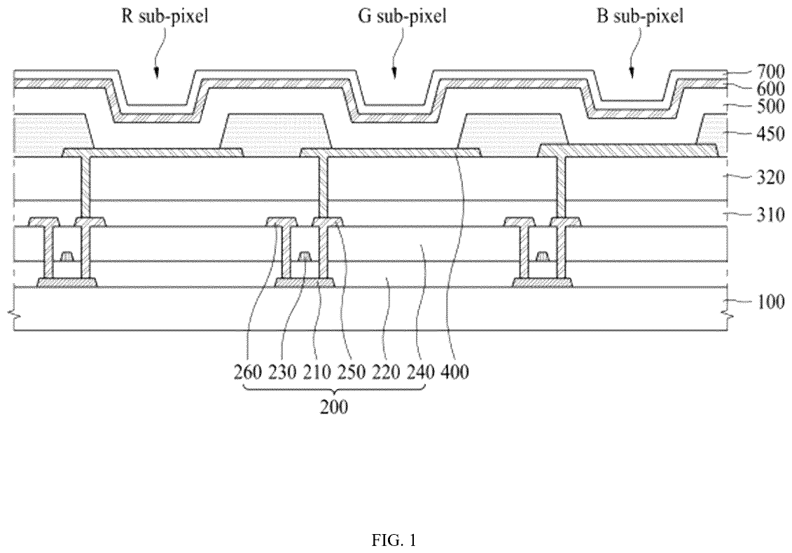

FIG. 1 is a schematic cross-sectional view of an electroluminescent display device according to an embodiment of the present disclosure.

As shown in FIG. 1, the electroluminescent display device according to an embodiment of the present disclosure includes a substrate 100, a circuit element layer 200, a passivation layer 310, a planarization layer 320, a first electrode 400, a bank 450, a light emitting unit 500, a second electrode 600, and a capping layer 700.

The substrate 100 may be made of glass, plastic, or semiconductor material, but is not limited thereto. The electroluminescent display device according to an embodiment of the present disclosure may be made of a top emission type, and accordingly, not only a transparent material but also an opaque material may be used as a material of the first substrate 100.

The circuit element layer 200 is disposed on the substrate 100.

The circuit element layer 200 includes a driving thin film transistor disposed for each of red, green, and blue sub-pixels (R sub-pixels, G sub-pixels, and B sub-pixels).

The driving thin film transistor includes an active layer 210 disposed on the substrate 100, a gate insulating layer 220 disposed on the active layer 210, a gate electrode 230 disposed on the gate insulating layer 220, an interlayer insulating layer 240 disposed on the gate electrode 230, and a source electrode 250 and a drain electrode 260 disposed on the interlayer insulating layer 240.

The source electrode 250 and the drain electrode 260 are connected to one side and the other side of the active layer 210 through holes disposed in the interlayer insulating layer 240 and the gate insulating layer 220.

Although a driving thin film transistor having a top gate structure in which the gate electrode 230 is disposed on the active layer 210 is illustrated in the drawing, the present disclosure may include a driving thin film transistor having a bottom gate structure in which the gate electrode 230 is disposed under the active layer 210. In addition, although the gate insulating layer 220 is disposed on an entire surface of the substrate 100, the gate insulating layer 220 may be patterned in the same manner as the gate electrode 230 under the gate electrode 230. The driving thin film transistor may be changed into various forms known in the art.

In addition, although not shown, the circuit element layer 200 may further include various signal lines including gate line, data line, power line, and reference line, various thin film transistors including switching thin film transistors and sensing thin film transistors, and capacitors.

The switching thin film transistor is switched according to a gate signal supplied to the gate line to supply a data voltage supplied from the data line to the driving thin film transistor.

The driving thin film transistor is switched according to the data voltage supplied from the switching thin film transistor to generate a data current from a power source supplied from the power line and supply the data current to the first electrode 400.

The sensing thin film transistor may sense a threshold voltage deviation of the driving thin film transistor, which causes image quality deterioration, and supplies a current of the driving thin film transistor to the reference line in response to a sensing control signal supplied from the gate line or a separate sensing line.

The capacitor may maintain the data voltage supplied to the driving thin film transistor for one frame, and be connected to a gate terminal and a source terminal of the driving thin film transistor, respectively.

The passivation layer 310 is disposed on the circuit element layer 200. Specifically, the passivation layer 310 is disposed on the source electrode 250 and the drain electrode 260. The passivation layer 310 may be formed of an inorganic insulating material, but is not limited thereto.

The planarization layer 320 is disposed on the passivation layer 310. The planarization layer 320 may be made of an organic insulating material.

The passivation layer 310 and the planarization layer 320 include a contact hole, and the source electrode 250 may be exposed through the contact hole, and the first electrode 400 may be connected to the source electrode 250 exposed through the contact hole. In some cases, the drain electrode 260 may be exposed through the contact hole disposed in the passivation layer 310 and the planarization layer 320, and the first electrode 400 may be connected to the drain electrode 260 exposed through the contact hole.

The first electrode 400 is disposed in each of sub-pixels (R sub-pixel, G sub-pixel, B sub-pixel) on the planarization layer 320.

The first electrode 400 is connected to the source electrode 250 or the drain electrode 260 through the contact hole disposed in the passivation layer 310 and the planarization layer 320.

The electroluminescent display device according to an embodiment of the present disclosure may be formed by the top emission type, and accordingly, the first electrode 400 may include a reflective electrode.

The bank 450 is disposed on the planarization layer 320, and is disposed at a boundary between sub-pixels (R sub-pixel, G sub-pixel, B sub-pixel).

The bank 450 is disposed on the first electrode 400 to cover an edge of the first electrode 400. A light emitting area may be defined by the bank 450. Specifically, a portion of the first electrode 400 exposed without being covered by the bank 450 may be a light emitting area.

The light emitting unit 500 is disposed in the light emitting area defined by the bank 450. The light emitting unit 500 is disposed on the first electrode 400, particularly, on a portion of the first electrode 400 exposed without being covered by the bank 450. In addition, the light emitting unit 500 may be disposed on an upper surface of the bank 450. That is, the light emitting unit 500 may also be disposed at a boundary between the sub-pixels (R sub-pixels, G sub-pixels, and B sub-pixels).

The light emitting unit 500 may be formed in various patterns, which will be described later.

The second electrode 600 is disposed on the light emitting unit 500.

The second electrode 600 is formed to be continuous across the sub-pixel (R sub-pixel, G sub-pixel, B sub-pixel).

The electroluminescent display device according to an embodiment of the present disclosure may be configured by the top emission type, and thus the second electrode 600 may include a transparent electrode or a translucent electrode.

The capping layer 700 is disposed on the second electrode 600. The capping layer 700 may include an organic insulating material, and may cover particles that may remain on an upper surface of the second electrode 600.

Although not shown, an encapsulation layer may be additionally disposed on the capping layer 700.

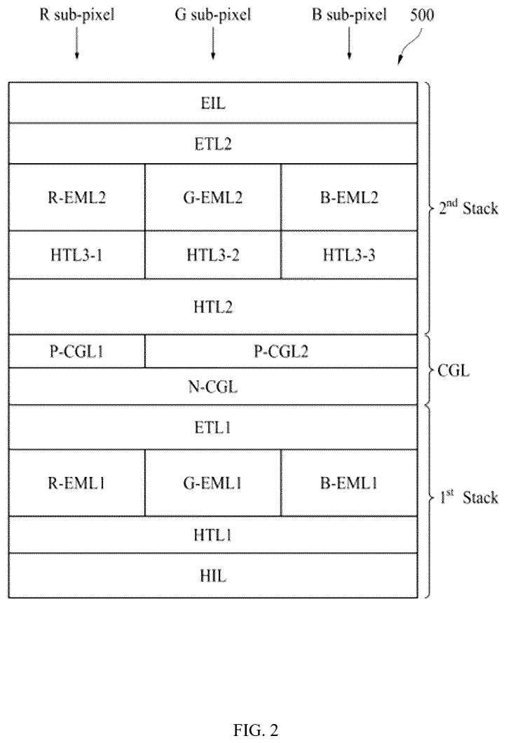

FIG. 2 is a schematic cross-sectional view of a light emitting unit according to an embodiment of the present disclosure.

As shown in FIG. 2, the light emitting unit 500 according to an embodiment of the present disclosure includes a first stack (1^{st} Stack), a second stack (2^{nd} Stack), and a charge generation layer CGL.

The first stack (1^{st} Stack) includes a hole injection layer HIL, a first hole transport layer HTL1, a first light emitting layer R-EML1, G-EML1, and B-EML1, and a first electron transport layer ETL1.

The hole injection layer HIL is disposed on the first electrode 400 and the bank 450 of FIG. 1 described above, and may be formed to be continuous across red, green, and blue sub-pixels (R sub-pixels, G sub-pixels, and B sub-pixels).

In the present disclosure, when a material layer is formed to be continuous across the plurality of sub-pixels, it means that the material layer is continuous in the plurality of sub-pixels and in a boundary area therebetween.

The first hole transport layer HTL1 is disposed on the hole injection layer HIL, and may be formed to be continuous across red, green, and blue sub-pixels (R sub-pixels, G sub-pixels, and B sub-pixels).

The first light emitting layers R-EML1, G-EML1, and B-EML1 are disposed on the first hole transport layer HTL1.

The first light emitting layers R-EML1, G-EML1, and B-EML1 include a first red light emitting layer R-EML1 disposed in the red sub-pixel, a first green light emitting layer G-EML1 disposed in the green sub-pixel, and a first blue light emitting layer B-EML1 disposed in the blue sub-pixel.

The first red light emitting layer R-EML1, the first green light emitting layer G-EML1, and the first blue light emitting layer B-EML1 may not overlap with each other, but are not limited thereto. In addition, the first red light emitting layer R-EML1, the first green light emitting layer G-EML1, and the first blue light emitting layer B-EML1 may be formed not to be in contact with each other.

The first electron transport layer ETL1 is disposed on the first light emitting layers R-EML1, G-EML1, and B-EML1, and may be formed to be continuous across red, green, and blue sub-pixels (R sub-pixels, G sub-pixels, and B sub-pixels).

Although not shown, the first stack (1^{st} Stack) may further include a hole blocking layer HBL disposed between the first light emitting layer R-EML1, G-EML1, and B-EML1 and the first electron transport layer ETL1.

The second stack (2^{nd} Stack) includes a second hole transport layer HTL2, third hole transport layers HTL3-1, HTL3-2, and HTL3-3, second light emitting layers R-EML2, G-EML2, B-EML2, a second electron transport layer ETL2, and an electron injection layer EIL.

The second hole transport layer HTL2 is disposed on the charge generation layer CGL. More particularly, the second hole transport layer HTL2 is disposed on a P-type charge generation layers P-CGL1 and P-CGL2. Also, the second hole transport layer HTL2 may be formed to be continuous across red, green, and blue sub-pixels (R sub-pixels, G sub-pixels, and B sub-pixels). The second hole transport layer HTL2 may be formed of the same material as the first hole transport layer HTL1, but is not limited thereto.

The third hole transport layers HTL3-1, HTL3-2, and HTL3-3 are disposed on the second hole transport layer HTL2.

The third hole transport layers HTL 3-1, HTL 3-2, and HTL 3-3 include a 3-1st hole transport layer HTL 3-1 disposed in the red sub-pixel(R sub-pixel), a 3-2nd hole transport layer HTL 3-2 disposed in the green sub-pixel(G sub-pixel), and a 3-3rd hole transport layer HTL 3-3 disposed in the blue sub-pixel(B sub-pixel).

The third hole transport layers HTL3-1, HTL3-2, and HTL3-3 are formed to obtain a microcavity effect for each sub-pixel (R sub-pixel, G sub-pixel, and B sub-pixel). The 3-1st hole transport layer HTL3-1 is for obtaining a microcavity effect in the red sub-pixel (R sub-pixel), and the 3-2nd hole transport layer HTL 3-2 is for obtaining a microcavity effect in the green sub-pixel (G sub-pixel), and the 3-3rd hole transport layer HTL 3-3 is for obtaining a microcavity effect in the blue sub-pixel (B sub-pixel).

Considering that red is a longer wavelength than green and green is a longer wavelength than blue, a thickness of the 3-1st hole transport layer HTL 3-1 may be greater than a thickness of the 3-2nd hole transport layer HTL 3-2, and the thickness of the 3-2nd hole transport layer HTL 3-2 may be greater than a thickness of the 3-3rd hole transport layer HTL 3-3. In the blue sub-pixel(B sub-pixel), a micro-cavity effect may be obtained by the second hole transport layer HTL2, and in this case, the 3-3rd hole transport layer HTL 3-3 may be omitted.

The third hole transport layers HTL3-1, HTL3-2, and HTL3-3 may be formed of the same material as the second hole transport layer HTL2 or the first hole transport layer HTL1, but are not limited thereto. The 3-1st hole transport layer HTL 3-1, the 3-2nd hole transport layer HTL 3-2, and the 3-3rd hole transport layer HTL 3-3 may be formed of the same material, but are not limited thereto.

The 3-1st hole transport layer HTL 3-1, the 3-2nd hole transport layer HTL 3-2, and the 3-3rd hole transport layer HTL 3-3 may not overlap with each other. In addition, the 3-1st hole transport layer HTL 3-1, the 3-2nd hole transport layer HTL 3-2, and the 3-3rd hole transport layer HTL3-3 may be formed not to be in contact with each other.

In some cases, the third hole transport layers HTL3-1, HTL3-2, and HTL3-3 may not be formed in the second stack (2^{nd} Stack), but may be formed in the first stack (1^{st} Stack). Specifically, the third hole transport layers HTL3-1, HTL3-2, and HTL3-3 may not be formed between the second hole transport layer HTL2 and the second light emitting layers R-EML2, G-EML2, and B-EML2, but may be formed between the first hole transport layer HTL1 and the first light emitting layers R-EML1, G-EML1, and B-EML1.

The second light emitting layers R-EML2, G-EML2, and B-EML2 are disposed on the third hole transport layers HTL3-1, HTL3-2, and HTL3-3.

The second light emitting layers R-EML2, G-EML2, and B-EML2 include the second red light emitting layer R-EML2 disposed in the red sub-pixel (R sub-pixel), the second green light emitting layer G-EML2 disposed in the green sub-pixel (G sub-pixel), and the second blue light emitting layer B-EML2 disposed in the blue sub-pixel (B sub-pixel).

The second red light emitting layer R-EML2, the second green light emitting layer G-EML2, and the second blue light emitting layer B-EML2 may not overlap with each other, but are not limited thereto. The second red light emitting layer R-EML2, the second green light emitting layer G-EML2, and the second blue light emitting layer B-EML2 may be formed not to be in contact with each other.

The second red light emitting layer R-EML2 may be formed of the same material as the first red light emitting layer R-EML1, but is not limited thereto. The second green light emitting layer G-EML2 may be formed of the same material as the first green light emitting layer G-EML1, but is not limited thereto. The second blue light emitting layer B-EML2 may be formed of the same material as the first blue light emitting layer B-EML1, but is not limited thereto.

The second electron transport layer ETL2 is disposed on the second light emitting layers R-EML2, G-EML2, and B-EML2, and may be formed to be continuous across red, green, and blue sub-pixels R sub-pixels (R sub-pixels, G sub-pixels, and B sub-pixels).

Although not shown, the second stack (2^{nd} Stack) may further include a hole blocking layer HBL disposed between the second light emitting layers R-EML2, G-EML2, and B-EML2 and the second electron transport layer ETL2.

The electron injection layer EIL is disposed on the second electron transport layer ETL2, and may be formed to be continuous across red, green, and blue sub-pixels (R sub-pixels, G sub-pixels, and B sub-pixels).

According to an embodiment of the present disclosure, the first light emitting layers R-EML1, G-EML1, and B-EML1 include the first red light emitting layer R-EML1, the first green light emitting layer G-EML1, and the first blue light emitting layer B-EML1, and the second light emitting layer R-EML2, G-EML2, and B-EML2 include the second red light emitting layer R-EML2, the second green light emitting layer G-EML2, and the second blue light emitting layer B-EML2. Accordingly, without a separate color filter, red light may be emitted from the red sub-pixel (R sub-pixel), green light may be emitted from the green sub-pixel (G sub-pixel), and blue light may be emitted from the blue sub-pixel (B sub-pixel).

However, the present disclosure is not necessarily limited thereto. For example, according to another embodiment of the present disclosure, one of the first light emitting layers between the first hole transport layer HTL1 and the first electron transport layer ETL1 and the second light emitting layer between the third hole transport layers HTL3-1, HTL3-2, and HTL3-3, and the second electron transport layer ETL2 includes a blue light emitting layer that is continuous across red, green, and blue sub-pixels (R sub-pixel, G sub-pixel, B sub-pixel), and the remaining light emitting layers include a yellow-green light emitting layer that is continuous across red, green, and blue sub-pixels (R sub-pixel, G sub-pixel, B sub-pixel). In this case, a red color filter is additionally disposed in the red sub-pixel (R sub-pixel), a green color filter is additionally disposed in the green sub-pixel (G sub-pixel), and a blue color filter is additionally disposed in the blue sub-pixel B sub-pixel (B sub-pixel).

The charge generation layer CGL is disposed between the first stack (1^{st} Stack) and the second stack (2^{nd} Stack). The charge generation layer CGL may be disposed between the first electron transport layer ETL1 and the second hole transport layer HTL2.

The charge generation layer CGL includes an N-type charge generation layer N-CGL and P-type charge generation layers P-CGL1 and P-CGL2.

The N-type charge generation layer N-CGL supplies electrons to the first stack (1^{st} Stack) and the P-type charge generation layers P-CGL1 and P-CGL2 supply holes to the second stack (2^{nd} Stack).

The N-type charge generation layer N-CGL is disposed on the first electron transport layer ETL1, and may be formed to be continuous across red, green, and blue sub-pixels (R sub-pixel, G sub-pixel, B sub-pixel).

The P-type charge generation layers P-CGL1 and P-CGL2 are disposed on the N-type charge generation layer N-CGL. The P-type charge generation layers P-CGL1 and P-CGL2 include a first P-type charge generation layer P-CGL1 and a second P-type charge generation layer P-CGL2.

The first P-type charge generation layer P-CGL1 is disposed in the red sub-pixel (R sub-pixel), and the second P-type charge generation layer P-CGL2 is disposed in the green sub-pixel and the blue sub-pixel (G sub-pixel and B sub-pixel)

The first P-type charge generation layer P-CGL1 may be patterned in an island structure in the red sub-pixel (R sub-pixel), and the second P-type charge generation layer P-CGL2 may be formed to be continuous across the green sub-pixel (G sub-pixel) and the blue sub-pixel (B sub-pixel).

The first P-type charge generation layer P-CGL1 and the second P-type charge generation layer P-CGL2 do not overlap with each other and are not in contact with each other.

The P-type charge generation layers P-CGL1 and P-CGL2 may be formed by doping an organic material with a metal dopant or a non-metal dopant such as an inorganic material or an organic material, and thus have good electrical conductivity. Therefore, if the P-type charge generation layers P-CGL1 and P-CGL2 are formed to be continuous across red, green, and blue sub-pixels (R sub-pixel, G sub-pixel, and B sub-pixel), electric charges may freely move between the sub-pixels (R sub-pixel, G sub-pixel, and B sub-pixel) through the P-type charge generation layers P-CGL1 and P-CGL2, resulting in a leakage current in adjacent sub-pixels.

Therefore, in order to prevent such a leakage current problem, it may be desirable to form the P-type charge generation layers P-CGL1 and P-CGL2 to be discontinuous without continuity between red, green, and blue sub-pixels (R sub-pixel, G sub-pixel, and B sub-pixel).

However, if the P-type charge generation layers P-CGL1 and P-CGL2 are formed to be discontinuous without continuity between the sub-pixels (R sub-pixel, G sub-pixel, and B sub-pixel), a resistance between the sub-pixels (R sub-pixel, G sub-pixel, and B sub-pixel) increases in a horizontal direction. Therefore, an electric charge may not move smoothly and may remain in a boundary area between the sub-pixels (R sub-pixel, G sub-pixel, and B sub-pixel). At this time, when an electric field is applied to the sub-pixels (R sub-pixel, G sub-pixel, and B sub-pixel), a leakage current is introduced into a stack with low resistance due to potential asymmetry between the first stack (1^{st} Stack) and the second stack (2^{nd} stack). Therefore, as light having a luminance higher than a desired luminance emits, a screen defect such as flash may occur. Such screen defects increase at a low gray scale.

In general, considering that a driving current is reduced in an order of the blue sub-pixel (B sub-pixel), the red sub-pixel (R sub-pixel), and the green sub-pixel (G sub-pixel), a large amount of electronic charge remaining in the boundary area intensively flows into the green sub-pixel (G sub-pixel), and screen defects such as flash increase in the green sub-pixel (G sub-pixel).

Therefore, according to an embodiment of the present disclosure, for example, by connecting the second P-type charge generation layer P-CGL2 of the blue sub-pixel (B sub-pixel) with the relatively largest driving current and the second P-type charge generation layer P-CGL2 of the green sub-pixel (G sub-pixel) with the relatively smallest driving current, it is possible to eliminate screen defects such as the flash by lowering the resistance in the horizontal direction between the blue sub-pixel (B sub-pixel) and the green sub-pixel (G sub-pixel) to prevent the remaining electronic charge in the boundary area.

However, the present disclosure is not necessarily limited thereto, and the second P-type charge generation layer P-CGL2 may be formed continuously across two sub-pixels among the blue sub-pixel (B sub-pixel), the red sub-pixel (R sub-pixel), and the green sub-pixel (G sub-pixel), and the first P-type charge generation layer P-CGL1 may be formed in the remaining sub-pixel.

In order to reduce a resistance between the blue sub-pixel (B sub-pixel) and the green sub-pixel (G sub-pixel) in the horizontal direction, an electrical conductivity of the second P-type charge generation layer P-CGL2 may be greater than an electrical conductivity of the first P-type charge generation layer P-CGL1.

The first P-type charge generation layer P-CGL1 may be formed by doping a first organic material with a first dopant such as metal, and the second P-type charge generation layer P-CGL2 may be formed by doping a second organic material with a second dopant such as metal.

In this case, the first organic material and the second organic material may be made of the same material, but are not necessarily limited thereto. In addition, the first dopant and the second dopant may be made of the same material, but are not necessarily limited thereto.

However, as a doping concentration of the second dopant is formed to be higher than a doping concentration of the first dopant, the electrical conductivity of the second P-type charge generation layer P-CGL2 may be higher than the electrical conductivity of the first P-type charge generation layer P-CGL1.

Alternatively, the doping concentration of the second dopant is the same as the doping concentration of the first dopant, but the electrical conductivity of the second P-type charge generation layer P-CGL2 may be greater than the electrical conductivity of the first P-type charge generation layer P-CGL1 by using the second dopant with a higher electrical conductivity than the first dopant.

Meanwhile, according to FIG. 2, the N-type charge generation layer N-CGL is formed to be continuous across red, green, and blue sub-pixels (R sub-pixel, G sub-pixel, and B sub-pixel), but the present disclosure is not limited thereto, and the N-type charge generation layer N-CGL may also be patterned in the same manner as the P-type charge generation layers P-CGL1 and P-CGL2.

Specifically, the N-type charge generation layer N-CGL may also consist of a first N-type charge generation layer patterned in the red sub-pixel (R sub-pixel) to an island structure, and a second N-type charge generation layer formed continuously across the green sub-pixel (G sub-pixel) and the blue sub-pixel (B sub-pixel).

In this case, the first N-type charge generation layer may have the same pattern as the first P-type charge generation layer P-CGL1, and the second N-type charge generation layer may have the same pattern as the second P-type charge generation layer P-CGL2.

An electrical conductivity of the second N-type charge generation layer may be greater than an electrical conductivity of the first N-type charge generation layer. For example, a dopant concentration included in the second N-type charge generation layer may be formed higher than a dopant concentration included in the first N-type charge generation layer, or a dopant included in the second N-type charge generation layer may have higher electrical conductivity than a dopant included in the first N-type charge generation layer.

In some cases, the P-type charge generation layer is formed to be continuous across red, green, and blue sub-pixels (R sub-pixel, G sub-pixel, B sub-pixel), and the N-type charge generation layer N-CGL may be formed of the first N-type charge generation layer and the second N-type charge generation layer. However, since the screen defect such as the flash is more likely to occur through the P-type charge generation layer than the N-type charge generation layer, it can be preferable that the P-type charge generation layer is formed to include the first P-type charge generation layer P-CGL1 and the second P-type charge generation layer P-CGL2 as shown in FIG. 2.

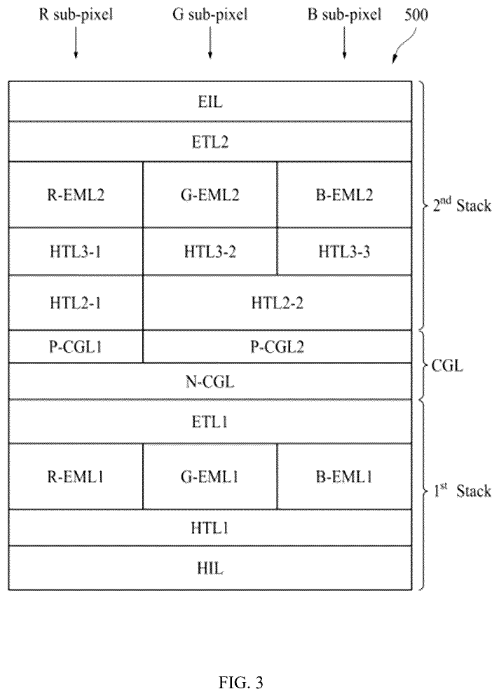

FIG. 3 is a schematic cross-sectional view of a light emitting unit according to another embodiment of the present disclosure.

FIG. 3 is different from FIG. 2 described above in that the second hole transport layer HTL2 is changed. Accordingly, the same reference numerals are assigned to the same configuration, and different configurations are to be described below. The same applies to other embodiments below.

As shown in FIG. 3, the second hole transport layer HTL2 includes a 2-1st hole transport layer HTL 2-1 and a 2-2nd hole transport layer HTL 2-2.

The 2-1st hole transport layer HTL 2-1 is disposed in the red sub-pixel (R sub-pixels), and the 2-2nd hole transport layer HTL 2-2 is disposed in the green sub-pixel and the blue sub-pixel (G sub-pixels and B sub-pixels).

The 2-1st hole transport layer HTL 2-1 may be formed in the same pattern as the first P-type charge generation layer P-CGL 1, and the 2-2nd hole transport layer HTL 2-2 may be formed in the same pattern as the second P-type charge generation layer P-CGL2.

Thus, the 2-1st hole transport layer HTL 2-1 may be patterned in the red sub-pixel (R sub-pixel) to an island structure, and the 2-2nd hole transport layer HTL 2-2 may be formed to be continuous across the green sub-pixel and the blue sub-pixel (G sub-pixels and B sub-pixels).

The 2-1st hole transport layer HTL 2-1 and the 2-2nd hole transport layer HTL 2-2 may be formed not to overlap with each other. In addition, the 2-1st hole transport layer HTL 2-1 and the 2-2nd hole transport layer HTL2-2 may be formed not to be in contact with each other.

Therefore, the electronic charge does not move in the horizontal direction between the 2-1st hole transport layer HTL2-1 and the 2-2ne hole transport layer HTL2-2, so that no leakage current is generated through the second hole transport layers HTL2-1 and HTL2-2 between the red sub-pixel (R sub-pixel) the green sub-pixel (G sub-pixel) and between the red sub-pixel (R sub-pixel) and the blue sub-pixel (B sub-pixel).

The 2-1st hole transport layer HTL 2-1 and the 2-2nd hole transport layer HTL 2-2 may be formed of the same material, but are not limited thereto.

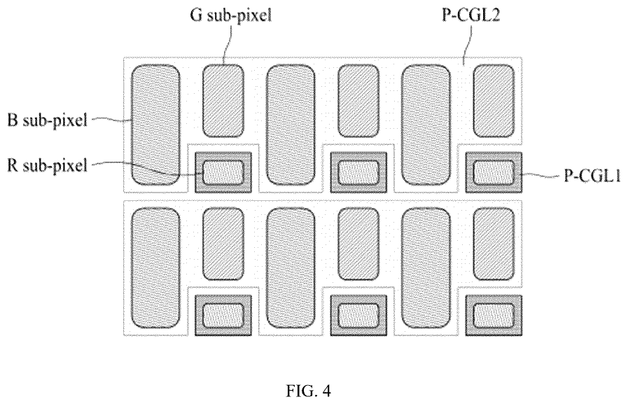

FIGS. 4 to 8 are schematic plan views of an electroluminescent display device according to various embodiments of the present disclosure. For convenience, only patterns of the first P-type charge generation layer P-CGL1 and the second P-type charge generation layer P-CGL2 disposed in the sub-pixel (R sub-pixel, G sub-pixel, and B sub-pixel) according to FIGS. 2 to 3 described above are illustrated in FIGS. 4 to 8.

As shown in FIGS. 4 to 8, an electroluminescent display device according to various embodiments of the present disclosure includes a plurality of pixels including a red sub-pixel (R sub-pixel), a green sub-pixel (G sub-pixel), and a blue sub-pixel (B sub-pixel).

Each of the plurality of pixels according to the present disclosure may be formed of a combination of the red sub-pixel (R sub-pixel), the green sub-pixel (G sub-pixel), and the blue sub-pixel (B sub-pixel), but is not necessarily limited thereto, and may further include a fourth sub-pixel.

As shown in FIGS. 4 to 8, the first P-type charge generation layer P-CGL1 may overlap with an entire area of the red sub-pixel (R sub-pixel). In addition, the first P-type charge generation layer P-CGL1 may overlap with a portion of a boundary area between the red sub-pixel (R sub-pixel) and the green sub-pixel (G sub-pixel) and a portion of a boundary area between the red sub-pixel (R sub-pixel) and the blue sub-pixel B (B sub-pixel).

The first P-type charge generation layer P-CGL1 does not overlap with the green sub-pixel (G sub-pixel) and the blue sub-pixel (B sub-pixel). In addition, the first P-type charge generation layer P-CGL1 is spaced apart from the second P-type charge generation layer P-CGL2.

The second P-type charge generation layer P-CGL2 may overlap with an entire area of the green sub-pixel (G sub-pixel) and the blue sub-pixel (B sub-pixel). In addition, the second P-type charge generation layer P-CGL2 may overlap with an entire area of a boundary between the green sub-pixel (G sub-pixel) and the blue sub-pixel (B sub-pixel). In addition, the second P-type charge generation layer P-CGL2 may overlap with a portion of a boundary area between the red sub-pixel (R sub-pixel) and the green sub-pixel (G sub-pixel), and a portion of a boundary area between the red sub-pixel (R sub-pixel) and the blue sub-pixel (B sub-pixel).

The second P-type charge generation layer P-CGL2 does not overlap with the red sub-pixel (R sub-pixel).

Hereinafter, a plurality of pixels of each of FIGS. 4 to 8 will be described in detail.

As shown in FIG. 4, the blue sub-pixel (B sub-pixel) may be spaced apart from the green sub-pixel (G sub-pixel) and the red sub-pixel (R sub-pixel) in a first direction, for example, in the horizontal direction. The blue sub-pixel (B sub-pixel) may be disposed at one side and, for example, at a left side of the green sub-pixel (G sub-pixel) and the red sub-pixel (R sub-pixel) to face each of the green sub-pixel (G sub-pixel) and the red sub-pixel (R sub-pixel).

The green sub-pixel (G sub-pixel) and the red sub-pixel (R sub-pixel) may be spaced apart from each other in a second direction, for example, in the vertical direction.

An area of the blue sub-pixel (B sub-pixel) may be greater than an area of the green sub-pixel (G sub-pixel) and an area of the red sub-pixel (R sub-pixel), and the area of the green sub-pixel (G sub-pixel) may be greater than the area of the red sub-pixel (R sub-pixel), but is not limited thereto.

Each of the blue sub-pixel (B sub-pixel), the green sub-pixel (G sub-pixel), and the red sub-pixel (R sub-pixel) may have a rectangular structure, for example, a rectangular structure having curved edges.

One pixel including a combination of the blue sub-pixel (B sub-pixel), the green sub-pixel (G sub-pixel), and the red sub-pixel (R sub-pixel) may be repeatedly arranged in the first direction and the second direction.

The second P-type charge generation layer P-CGL2 is continuous across the blue sub-pixel (B sub-pixel) and the green sub-pixel (G sub-pixel) of two or more pixels in the horizontal direction.

The second P-type charge generation layer P-CGL2 may be discontinuous across two or more pixels in the vertical direction, but is not limited thereto, and may be continuous across two or more pixels in the vertical direction.

The second P-type charge generation layer P-CGL2 may be continuous across all pixels in the horizontal direction and the vertical direction.

The first P-type charge generation layer P-CGL1 is patterned in an island structure in the red sub-pixel (R sub-pixel). The first P-type charge generation layer P-CGL1 may have an island structure in the red sub-pixel (R sub-pixel) of an entire plurality of pixels.

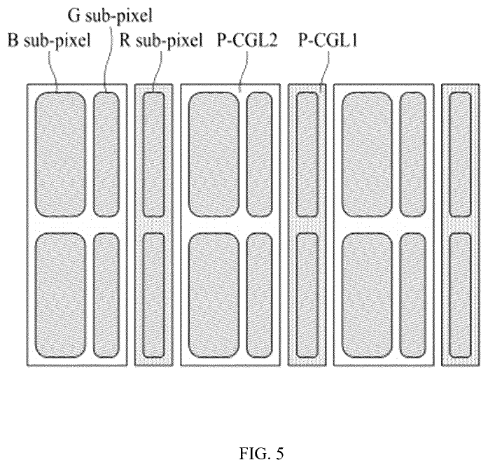

As shown in FIG. 5, the blue sub-pixel (B sub-pixel), the green sub-pixel (G sub-pixel), and the red sub-pixel (R sub-pixel) may be sequentially arranged in the first direction, for example, in the horizontal direction.

An area of the blue sub-pixel (B sub-pixel) may be greater than an area of the green sub-pixel (G sub-pixel) and an area of the red sub-pixel (R sub-pixel), and the area of the green sub-pixel (G sub-pixel) may be greater than the area of the red sub-pixel (R sub-pixel), but is not limited thereto.

Each of the blue sub-pixel (B sub-pixel), the green sub-pixel (G sub-pixel), and the red sub-pixel (R sub-pixel) may have a rectangular structure, for example, a rectangular structure having curved edges.

One pixel including a combination of the blue sub-pixel (B sub-pixel), the green sub-pixel (G sub-pixel), and the red sub-pixel (R sub-pixel) may be repeatedly arranged in the first direction and the second direction.

The second P-type charge generation layer P-CGL2 is continuous across an entire blue sub-pixel (B-pixel) and the green sub-pixel (G sub-pixel) of two or more pixels in the vertical direction. However, the second P-type charge generation layer P-CGL2 is discontinuous across the plurality of pixels in the horizontal direction.

The first P-type charge generation layer P-CGL1 may be continuous across the red sub-pixel (R sub-pixel) of two or more pixels in the vertical direction. However, the first P-type charge generation layer P-CGL1 is discontinuous across the red sub-pixel (R sub-pixel) of the plurality of pixels in the horizontal direction.

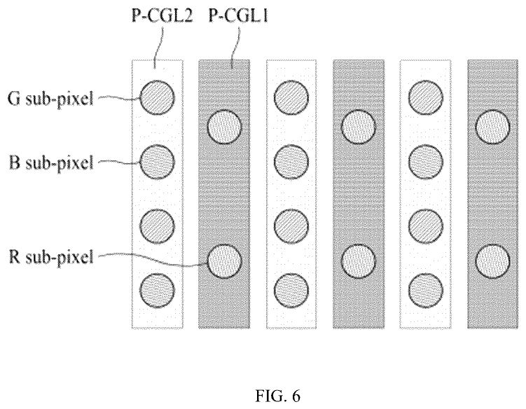

As shown in FIG. 6, the green sub-pixel (G sub-pixel) and the blue sub-pixel (B sub-pixel) may be spaced apart from the red sub-pixel (R sub-pixel) in the first direction, for example, in the horizontal direction.

The green sub-pixel (G sub-pixel) and the red sub-pixel (R sub-pixel) may be spaced apart from each other in the second direction, for example, in the vertical direction.

The green sub-pixel (G sub-pixel), the blue sub-pixel (B sub-pixel), and the red sub-pixel (R sub-pixel) may be arranged to form a triangle vertex.

Each of the green sub-pixel (G sub-pixel), the blue sub-pixel (B sub-pixel), and the red sub-pixel (R sub-pixel) may have a circular structure.

One pixel including a combination of the blue sub-pixel (B sub-pixel), the green sub-pixel (G sub-pixel), and the red sub-pixel (R sub-pixel) may be repeatedly arranged in the first direction and the second direction.

The second P-type charge generation layer P-CGL2 is continuous across an entire blue sub-pixel (B-pixel) and the green sub-pixel (G sub-pixel) of two or more pixels. However, the second P-type charge generation layer P-CGL2 is discontinuous across the plurality of pixels in the horizontal direction.

The first P-type charge generation layer P-CGL1 may be continuous across the red sub-pixel (R sub-pixel) of two or more pixels in the vertical direction. However, the first P-type charge generation layer P-CGL1 is discontinuous across the red sub-pixel (R sub-pixel) of the plurality of pixels in the horizontal direction.

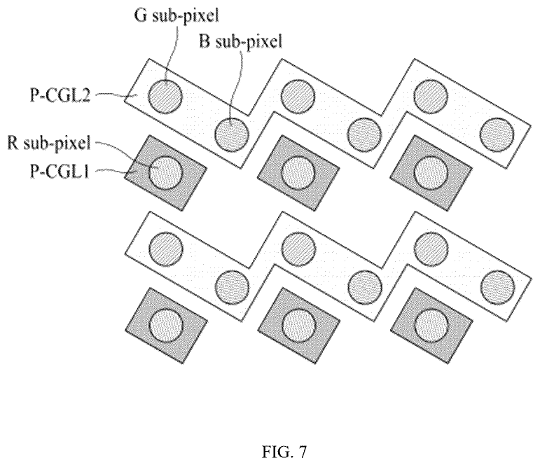

As shown in FIG. 7, the green sub-pixel (G sub-pixel) and the blue sub-pixel (B sub-pixel) may be separated from the red sub-pixel (R sub-pixel) in a diagonal direction, for example, from an upper right to a lower left.

The green sub-pixel (G sub-pixel) and the red sub-pixel (R sub-pixel) may be spaced apart from each other in a diagonal direction, for example, from an upper left to a lower right.

The combination of one green sub-pixel (G sub-pixel) and one red sub-pixel (R sub-pixel) is repeatedly arranged in the first direction, for example, in the horizontal direction while forming a zigzag shape.

The green sub-pixel (G sub-pixel), the blue sub-pixel (B sub-pixel), and the red sub-pixel (R sub-pixel) may be arranged to form a triangle vertex.

Each of the green sub-pixel (G sub-pixel), the blue sub-pixel (B sub-pixel), and the red sub-pixel (R sub-pixel) may have a circular structure.

One pixel including a combination of the blue sub-pixel (B sub-pixel), the green sub-pixel (G sub-pixel), and the red sub-pixel (R sub-pixel) may be repeatedly arranged in the first direction and the second direction.

The second P-type charge generation layer P-CGL2 is continuous across an entire blue sub-pixel (B-pixel) and the green sub-pixel (G sub-pixel) of two or more pixels in the horizontal direction.

The second P-type charge generation layer P-CGL2 may be discontinuous across two or more pixels in the vertical direction, but is not limited thereto, and may be continuous without being discontinuous by being extended through a boundary area between two red sub-pixels (R sub-pixel) in a plurality of pixels in the vertical direction. In this case, the second P-type charge generation layer P-CGL2 may be continuous in all pixels in the horizontal direction and the vertical direction.

The first P-type charge generation layer P-CGL1 may have an island structure while being discontinuous across the red sub-pixel (R sub-pixel) of the plurality of pixels. However, the present disclosure is not limited thereto, and the first P-type charge generation layer P-CGL1 may be continuous across the red sub-pixel (R sub-pixel) of two or more pixels in the horizontal direction.

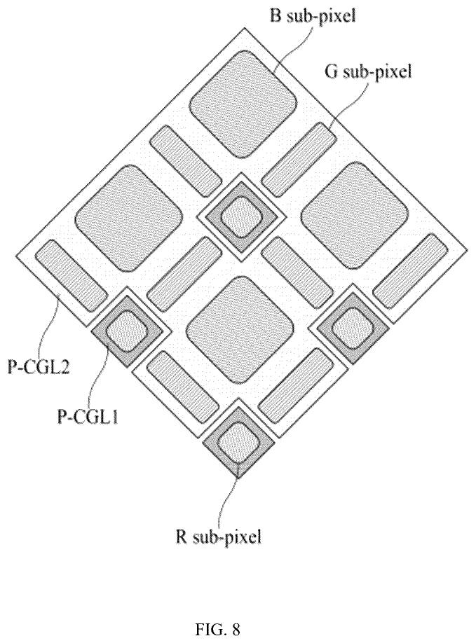

As shown in FIG. 8, a pixel may include two green sub-pixels (G sub-pixel). For example, two green sub-pixels (G sub-pixel) may be spaced apart from the blue sub-pixel (B sub-pixel) in a diagonal direction of the blue sub-pixel (B sub-pixel).

One green sub-pixel (G sub-pixel) may be spaced apart from the blue sub-pixel (B sub-pixel) in a lower right of the blue sub-pixel (B sub-pixel), and the other green sub-pixel (G sub-pixel) may be spaced apart from the blue sub-pixel (B sub-pixel) in a lower left of the blue sub-pixel.

In addition, the red sub-pixel (R sub-pixel) may be spaced apart from the blue sub-pixel (B sub-pixel) in the second direction, for example, in the vertical direction.

Each of the blue sub-pixel (B sub-pixel), the green sub-pixel (G sub-pixel), and the red sub-pixel (R sub-pixel) may have a rectangular structure, for example, a rectangular structure having curved edges.

The pixel having a rectangular structure as a whole is formed by a combination of the two green sub-pixels (G sub-pixel), the blue sub-pixel (B sub-pixel), and the red sub-pixel (R sub-pixel), and such the pixel may be repeated in a diagonal direction.

The second P-type charge generation layer P-CGL2 is continuous across the entire blue sub-pixel (B sub-pixel) and the green sub-pixel (G sub-pixel) of the plurality of pixels.

The first P-type charge generation layer P-CGL1 may have an island structure while being discontinuous across the red sub-pixel (R sub-pixel) of the plurality of pixels without being continuous.

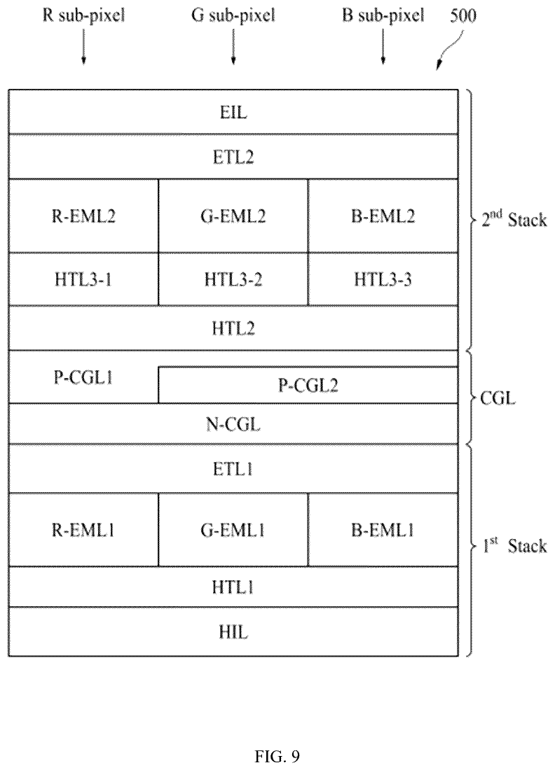

FIG. 9 is a schematic cross-sectional view of a light emitting unit according to another embodiment of the present disclosure.

FIG. 9 is different from FIG. 2 described above in that the P-type charge generation layers P-CGL1 and P-CGL2 are changed.

As shown in FIG. 9, the first P-type charge generation layer P-CGL1 may be formed to be continuous across red, green, and blue sub-pixels (R sub-pixels, G sub-pixels, and B sub-pixels).

As in FIG. 2 described above, the second P-type charge generation layer P-CGL2 may be formed to be continuous across the green sub-pixel and the blue sub-pixel (G sub-pixels and B sub-pixels).

The second P-type charge generation layer P-CGL2 is disposed under the first P-type charge generation layer P-CGL1 and may be in contact with the first P-type charge generation layer P-CGL1.

According to another embodiment of the present disclosure, by connecting the second P-type charge generation layer P-CGL2 of the blue sub-pixel (B sub-pixel) with the relatively largest driving current and the second P-type charge generation layer P-CGL2 of the green sub-pixel (G sub-pixel) with the relatively smallest driving current, it is possible to eliminate screen defects such as the flash by lowering the resistance in the horizontal direction between the blue sub-pixel (B sub-pixel) and the green sub-pixel (G sub-pixel) to prevent the remaining electronic charge in the boundary area.

However, the present disclosure is not necessarily limited thereto, and the second P-type charge generation layer P-CGL2 may be formed continuously between the blue sub-pixel (B sub-pixel) and the red sub-pixel (R sub-pixel) or between the red sub-pixel (R sub-pixel) and the green sub-pixel (G sub-pixel).

Meanwhile, as shown in FIG. 2, the N-type charge generation layer N-CGL may include a first N-type charge generation layer formed to be continuous across the red, green, and blue sub-pixels (R sub-pixel, G sub-pixel and B sub-pixel), and a second N-type charge generation layer formed to be continuous across the green sub-pixel and the blue sub-pixel (G sub-pixel and B sub-pixel). That is, the first N-type charge generation layer may be formed in the same pattern as the first P-type charge generation layer P-CGL1, and the second N-type charge generation layer may be formed in the same pattern as the second P-type charge generation layer P-CGL2.

In some cases, the P-type charge generation layer may be formed to be continuous across the red, green, and blue sub-pixel (R sub-pixel, G sub-pixel and B sub-pixel), and the N-type charge generation layer N-CGL may be formed of the first N-type charge generation layer and the second N-type charge generation layer.

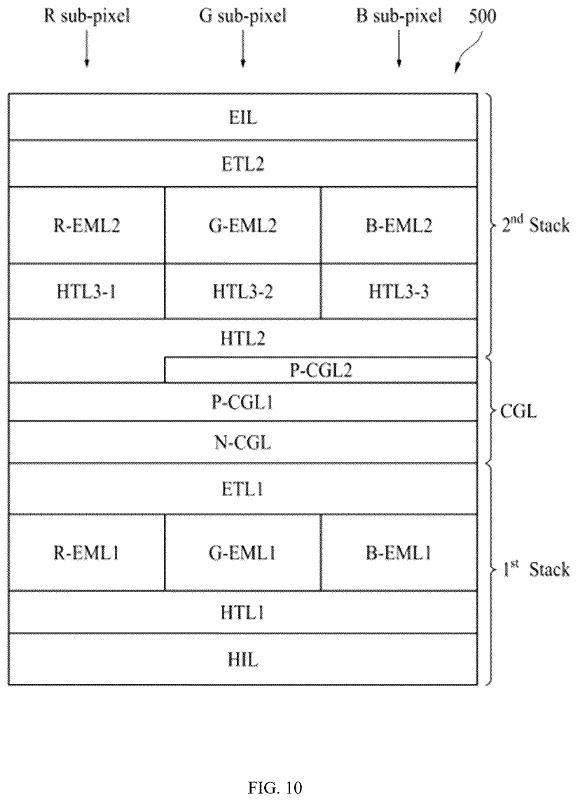

FIG. 10 is a schematic cross-sectional view of a light emitting unit according to another embodiment of the present disclosure.

FIG. 10 is different from FIG. 9 in that the second P-type charge generation layer P-CGL2 is disposed on the first P-type charge generation layer P-CGL1 and is in contact with the first P-type charge generation layer P-CGL1.

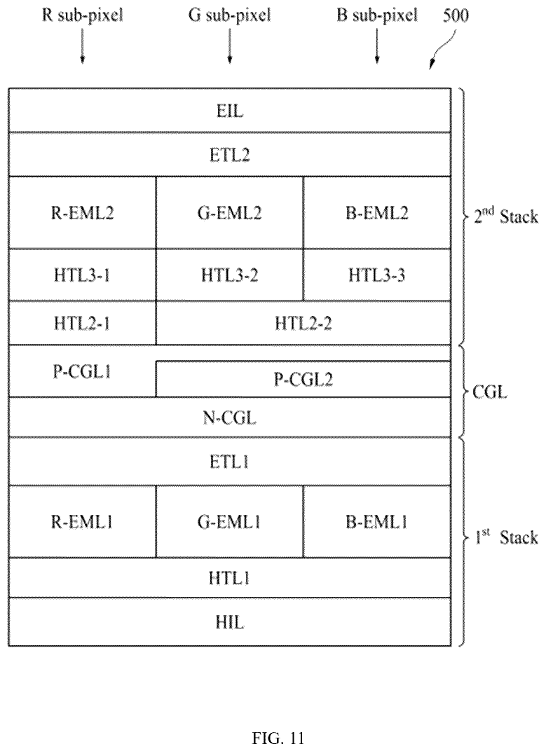

FIG. 11 is a schematic cross-sectional view of a light emitting unit according to another embodiment of the present disclosure.

FIG. 11 is different from FIG. 9 described above in that the second hole transport layer HTL2 is changed.

As shown in FIG. 11, the second hole transport layer HTL2 includes a 2-1st hole transport layer HTL 2-1 and a 2-2nd hole transport layer HTL 2-2.

The 2-1st hole transport layer HTL 2-1 is disposed in the red sub-pixel (R sub-pixel), and the 2-2nd hole transport layer HTL 2-2nd is disposed in the green sub-pixel and the blue sub-pixel (G sub-pixel and B sub-pixel).

The 2-1st hole transport layer HTL 2-1 may be patterned in an island structure in the red sub-pixel (R sub-pixel), and the 2-2nd hole transport layer HTL 2-2 may be formed to be continuous across the green sub-pixel and the blue sub-pixel (G sub-pixel and B sub-pixel).

The 2-1st hole transport layer HTL 2-1 and the 2-2nd hole transport layer HTL 2-2 may be formed not to overlap with each other. In addition, the 2-1st hole transport layer HTL 2-1 and the 2-2nd hole transport layer HTL2-2 may be formed not to be in contact with each other.

Therefore, an electronic charge does not move between the 2-1st hole transport layer HTL 2-1 and the 2-2nd hole transport layer HTL 2-2 in the horizontal direction, so that no leakage current is generated through the second hole transport layers HTL2-1 and HTL2-2 between the red sub-pixel (R sub-pixel) and the green sub-pixel (G sub-pixel), and between the red sub-pixel (R sub-pixel) and the blue sub-pixel (B sub-pixel).

The 2-1st hole transport layer HTL 2-1 and the 2-2nd hole transport layer HTL 2-2 may be formed of the same material, but are not limited thereto.

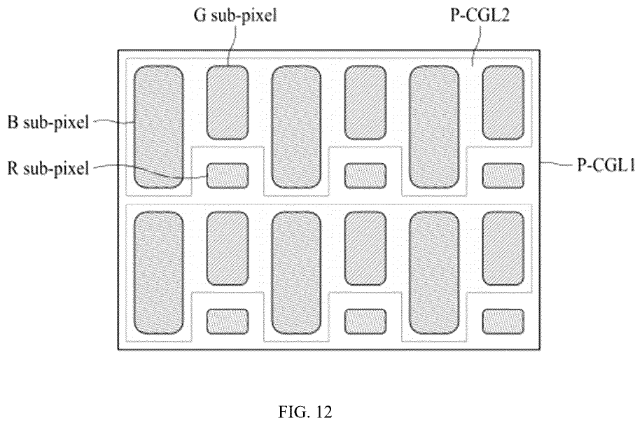

FIGS. 12 to 16 are schematic plan views of an electroluminescent display device according to various embodiments of the present disclosure. For convenience, only patterns of the first P-type charge generation layer P-CGL1 and the second P-type charge generation layer P-CGL2 provided in the sub-pixel (R sub-pixel, G sub-pixel and B sub-pixel) of FIGS. 9 to 11 described above are shown in FIGS. 12 to 16.

FIG. 12 differs from FIG. 4 in that the first P-type charge generation layer P-CGL1 is continuous across all sub-pixels (R sub-pixel, G sub-pixel, B sub-pixel) of the plurality pixels in the horizontal and vertical directions.

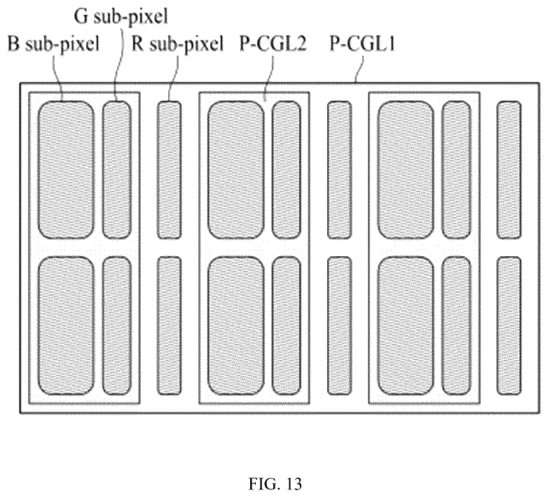

FIG. 13 differs from FIG. 5 in that the first P-type charge generation layer P-CGL1 is continuous across all sub-pixels (R sub-pixel, G sub-pixel, B sub-pixel) of the plurality pixels in the horizontal and vertical directions.

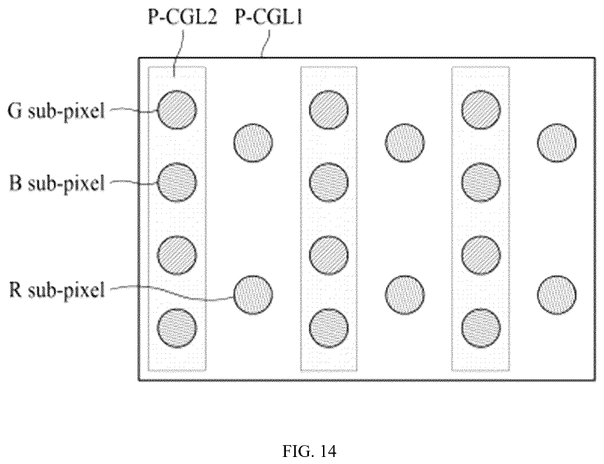

FIG. 14 differs from FIG. 6 in that the first P-type charge generation layer P-CGL1 is continuous across all sub-pixels (R sub-pixel, G sub-pixel, B sub-pixel) of the plurality pixels in the horizontal and vertical directions.

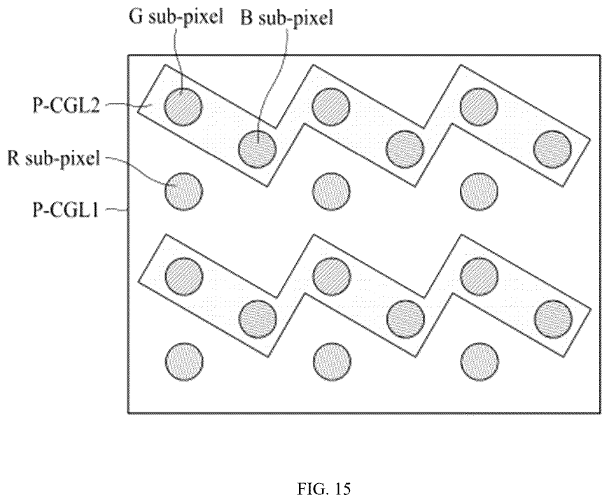

FIG. 15 differs from FIG. 7 in that the first P-type charge generation layer P-CGL1 is continuous across all sub-pixels (R sub-pixel, G sub-pixel, B sub-pixel) of the plurality pixels in the horizontal and vertical directions.

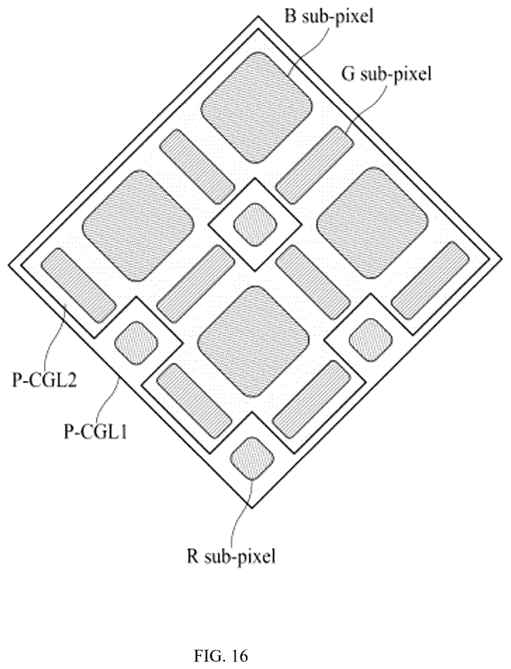

FIG. 16 differs from FIG. 8 in that the first P-type charge generation layer P-CGL1 is continuous across all sub-pixels (R sub-pixel, G sub-pixel, and B sub-pixel) of the plurality pixels in the diagonal direction.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. An electroluminescent display device comprising:
a substrate comprising a first sub-pixel, a second sub-pixel, and a third sub-pixel;
a first electrode in each of the first to third sub-pixels on the substrate;
a light emitting unit on the first electrode; and
a second electrode on the light emitting unit,
wherein the light emitting unit comprises a first stack comprising a first light emitting layer, a second stack comprising a second light emitting layer, and a charge generation layer disposed between the first stack and the second stack,
wherein the charge generation layer comprises a first charge generation layer disposed in the first sub-pixel and a second charge generation layer disposed in the second sub-pixel and the third sub-pixel, and
wherein the second charge generation layer does not overlap with the first sub-pixel and is continuous across the second sub-pixel and the third sub-pixel.

2. The electroluminescent display device of claim 1, wherein an electrical conductivity of the second charge generation layer is greater than an electrical conductivity of the first charge generation layer.

3. The electroluminescent display device of claim 1, wherein the charge generation layer comprises an N-type charge generation layer and a P-type charge generation layer, and wherein the P-type charge generation layer comprises the first charge generation layer and the second charge generation layer.

4. The electroluminescent display device of claim 1, wherein one of the second sub-pixel and the third sub-pixel is a blue sub-pixel, and the other of the second sub-pixel and the third sub-pixel is a green sub-pixel.

5. The electroluminescent display device of claim 1, wherein the first charge generation layer does not overlap with the second sub-pixel and the third sub-pixel.

6. The electroluminescent display device of claim 1, wherein the first charge generation layer is spaced apart from the second charge generation layer.

7. The electroluminescent display device of claim 1, wherein the first charge generation layer is continuous across the first sub-pixel, the second sub-pixel, and the third sub-pixel.

8. The electroluminescent display device of claim 7, wherein the second charge generation layer is disposed above or below the first charge generation layer.

9. The electroluminescent display device of claim 1, wherein the second stack comprises a hole transport layer disposed on the charge generation layer,
wherein the hole transport layer comprises a first hole transport layer disposed in the first sub-pixel and a second hole transport layer disposed in the second sub-pixel and the third sub-pixel, and
wherein the second hole transport layer does not overlap with the first sub-pixel and is continuous across the second sub-pixel and the third sub-pixel.

10. The electroluminescent display device of claim 9, wherein the first hole transport layer has a same pattern as the first charge generation layer, and the second hole transport layer has a same pattern as the second charge generation layer.

11. An electroluminescent display device comprising:
a plurality of pixels comprising a first sub-pixel, a second sub-pixel, and a third sub-pixel, wherein the plurality of pixels is arranged in a first direction and a second direction; and
a light emitting unit disposed in the plurality of pixels and comprising a charge generation layer,
wherein the charge generation layer comprises a first charge generation layer disposed in the first sub-pixel and a second charge generation layer that does not overlap with the first sub-pixel and is continuous across the second sub-pixel and the third sub-pixel, and
wherein the second charge generation layer is continuous across two or more pixels arranged in the first direction.

12. The electroluminescent display device of claim 11, wherein the second charge generation layer is discontinuous across the plurality of pixels arranged in the second direction.

13. The electroluminescent display device of claim 11, wherein the second charge generation layer is continuous across an entire plurality of pixels arranged in the first direction and the second direction.

14. The electroluminescent display device of claim 11, wherein the first charge generation layer is disposed in an island structure in an entire plurality of pixels arranged in the first direction and the second direction.

15. The electroluminescent display device of claim 11, wherein the first charge generation layer is continuous across two or more pixels arranged in the first direction.

16. The electroluminescent display device of claim 11, wherein the first charge generation layer is continuous across an entire plurality of pixels arranged in the first direction and the second direction.

17. The electroluminescent display device of claim 11, wherein an electrical conductivity of the second charge generation layer is greater than an electrical conductivity of the first charge generation layer.

18. The electroluminescent display device of claim 11, wherein the charge generation layer comprises an N-type charge generation layer and a P-type charge generation layer, and wherein the P-type charge generation layer comprises the first charge generation layer and the second charge generation layer.

19. The electroluminescent display device of claim 11, wherein one of the second sub-pixel and the third sub-pixel is a blue sub-pixel, and the other of the second sub-pixel and the third sub-pixel is a green sub-pixel.
